(19) United States
(12) Patent Application Publication
(10) Pub. No.: US 2014/0011371 A1
(43) Pub. Date: Jan. 9, 2014

(54) SILICON OXIDE FILM FORMING METHOD AND APPARATUS

(71) Applicant: TOKYO ELECTRON LIMITED, Tokyo (JP)

(72) Inventors: Tomoyuki OBU, Nirasaki City (JP); Masaki KUROKAWA, Nirasaki City (JP)

(73) Assignee: TOKYO ELECTRON LIMITED, Tokyo (JP)

(21) Appl. No.: 13/933,902

(22) Filed: Jul. 2, 2013

(30) Foreign Application Priority Data
Jul. 4, 2012 (JP) 2012-150758

(51) Int. Cl. H01L 21/02

(52) U.S. Cl. CPC H01L 21/02164; H01L 21/02104
USPC 438/787; 118/696

(57) ABSTRACT

A silicone oxide film forming method includes forming a silicon oxide film on a plurality of target objects by supplying a chlorine atom-containing silicon source into a reaction chamber accommodating the plurality of target objects. Forming the silicon oxide film includes making an interior of the reaction chamber be under a hydrogen atmosphere by supplying a hydrogen gas into the reaction chamber.

### CROSS-REFERENCE TO RELATED APPLICATION

This application claims the benefit of and priority from Japanese Patent Application No. 2012-150758, filed on Jul. 4, 2012, in the Japan Patent Office, the disclosure of which is incorporated herein in its entirety by reference.

### TECHNICAL FIELD

The present disclosure relates to a silicon oxide film forming method and a silicon oxide film forming apparatus.

### BACKGROUND

A thin film forming process, which forms a thin film such as a silicon oxide film on target objects (e.g., semiconductor wafers), is performed through a Chemical Vapor Deposition (CVD) method in a manufacture process of a semiconductor device. Such thin film forming process may improve the film quality by reducing an impurity concentration in the film during the film formation at a high temperature. For example, a silicon oxide film (i.e., a High Temperature Oxide (HTO) film) may be formed at a high temperature of about 800 degrees C. by the CVD method.

Further, to greatly improve a resistance against a dilute hydrofluoric acid (DHF) in the silicon oxide film formed by the CVD method, the silicone oxide film is doped with impurity, for example, C₂H₄, NH₃ or the like.

However, doping the silicon oxide film with the impurity such as C₂H₄ or NH₃ may deteriorate resistances against other chemicals (e.g., H₃PO₄) or affect a device performance.

### SUMMARY

Various embodiments of the present disclosure provide a silicon oxide film forming method and a silicon oxide film forming apparatus, which improve an etching resistance but do not degrade a device performance.

According to a first aspect of the present disclosure, there is provided a silicone oxide film forming method including forming a silicon oxide film on a plurality of target objects by supplying a chlorine atom-containing silicon source into a reaction chamber accommodating the plurality of target objects. Forming the silicon oxide film includes making an interior of the reaction chamber be under a hydrogen atmosphere by supplying a hydrogen gas into the reaction chamber.

According to a second aspect of the present disclosure, there is provided a silicone oxide film forming apparatus including a film forming gas supply unit, a hydrogen supply unit and a control unit. The film forming gas supply unit is configured to supply a film forming gas, which has a chlorine atom-containing silicon source, into a reaction chamber accommodating a plurality of target objects. The hydrogen supply unit is configured to supply a hydrogen gas into the reaction chamber. The control unit is configured to control the film forming gas supply unit and the hydrogen supply unit. The control unit controls the hydrogen supply unit such that the hydrogen supply unit supplies the hydrogen gas into the reaction chamber, making an interior of the reaction chamber under a hydrogen atmosphere. Further, the control unit controls the film forming gas supply unit such that the film forming gas supply unit supplies the film forming gas into the reaction chamber, thus forming a silicon oxide film on the plurality of target objects.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 shows a heat treatment apparatus according to an embodiment of the present disclosure.

FIG. 2 shows a configuration of a control unit shown in FIG. 1.

FIG. 3 is a diagram illustrating a recipe relating to a silicon oxide film forming method according to an embodiment of the present disclosure.

FIG. 4 is a graph showing a wet etching rate in DHF.

FIG. 5 is a graph showing the concentrations of hydrogen and chlorine contained in a silicon oxide film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

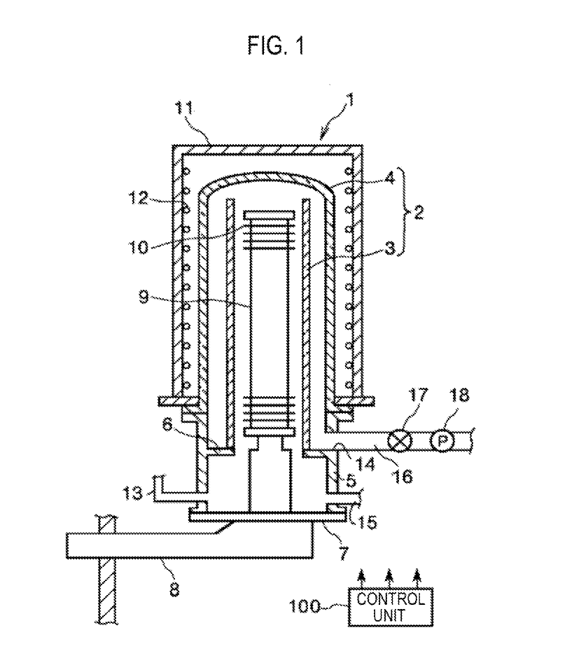

Descriptions will be made below as to embodiments of a silicon oxide film method and a silicon oxide film forming apparatus. These embodiments will be described with an example where a vertical batch-type heat treatment apparatus shown in FIG. 1 is used as a silicon oxide film forming apparatus.

As shown in FIG. 1, a heat treatment apparatus 1 includes a cylindrical reaction tube (an example of a reaction chamber) 2, vertically oriented. The reaction tube 2 has a double tube structure, which comprises an inner tube 3 and an outer tube 4 with a ceiling. The outer tube 4 is configured to cover up the inner tube 3 with a uniform spacing inbetween. The inner tube 3 and the outer tube 4 are made of a material having excellent thermal resistance and corrosion resistance, for example, quartz.

A manifold 5, which is formed in a cylindrical shape and is made of stainless steel, is disposed beneath the outer tube 4. The manifold 5 is air-tightly connected to a lower end of the outer tube 4. Further, a support ring 6 supports the inner tube 3. The support ring 6 protrudes from an inner wall of the manifold 5 and is integrally formed together with the manifold 5.

A lid 7 is disposed beneath the manifold 5. The lid 7 is configured to move in a vertical direction by a boat elevator 8. If the lid 7 is elevated by the boat elevator 8, then the lower portion of the manifold 5 (a furnace throat portion) is closed. If the lid 7 is lowered by the boat elevator 8, then the lower portion of the manifold 5 (a furnace throat portion) is opened.

A wafer boat 9, which is made of, for example, quartz, is placed on the lid 7. The wafer boat 9 is configured such that a plurality of target objects (e.g., semiconductor wafers 10) are vertically accommodated at a predetermined spacing.

A thermal insulator 11 is provided around the reaction tube 2 to surround the reaction tube 2. Temperature raising heaters 12, which comprise, for example, a resistance heating element, are provided on an inner wall surface of the thermal insulator 11. The temperature raising heaters 12 heat the interior of the reaction tube 2 to a predetermined temperature, thereby heating semiconductor wafers 10 to a predetermined temperature.

A plurality of processing gas introduction pipes 13 are inserted through (connected to) a side wall of the manifold 5. Only one of the processing gas introduction pipes 13 is shown in FIG. 1. The processing gas introduction pipes 13 are disposed to face to the interior of the inner tube 3. For example, as shown in FIG. 1, the processing gas introduction pipes 13 are inserted through the side wall of the manifold 5 that is below the support ring 6 (below the inner tube 3).

A processing gas supply source (not shown) is connected to the processing gas introduction pipes 13 via a mass flow controller (not shown). Thus, a desired amount of processing gas is supplied from the processing gas supply source into the reaction tube 2 through the processing gas introduction pipes 13. For example, the processing gas supplied from the processing gas introduction pipes 13 may include a film forming gas for formation of a silicon oxide film and a hydrogen gas for making the interior of the reaction tube 2 be under a hydrogen (H₂) atmosphere during film formation. The film forming gas includes an oxidizing agent and a silicon source containing chlorine atoms. The chlorine atom-containing silicon source may include tetrachlorosilane, trichlorosilane, dichlorosilane (DCS), monochlorosilane, hexachlorodisilane (HCD) or the like. The oxidizing agent may include nitrous oxide (N₂O), nitrogen monoxide (NO), nitrogen dioxide (NO₂), ozone (O₃) or the like.

An exhaust port 14 for evacuating the gas in the reaction tube 2 is provided in the side wall of the manifold 5. The exhaust port 14 is positioned above the support ring 6 and connected to a space defined between the inner tube 3 and the outer tube 4 in the reaction tube 2. An exhaust gas, which is produced from the inner tube 3, passes through the space between the inner tube 3 and the outer tube 4 and is evacuated through the exhaust port 14.

A purge gas supply pipe 15 is inserted through the side wall of the manifold 5 below the exhaust port 14. A purge gas supply source (not shown) is connected to the purge gas supply pipe 15. A desired amount of purge gas (e.g., nitrogen gas) is supplied from the purge gas supply source into the reaction tube 2 through the purge gas supply pipe 15.

An exhaust pipe 16 is air-tightly connected to the exhaust port 14. The exhaust pipe 16 is equipped with a valve 17 and a vacuum pump 18 from the upstream side of the exhaust pipe 16. The valve 17 adjusts an opening of the exhaust pipe 16 controlling a pressure in the reaction tube 2 to a predetermined pressure. The vacuum pump 18 evacuates the gas in the reaction tube 2 through the exhaust pipe 16 and adjusts the pressure in the reaction tube 2.

Further, the exhaust pipe 16 is equipped with a trap (not shown), a scrubber (not shown), etc. The exhaust pipe 16 is configured to detoxify the exhaust gas evacuated from the reaction tube 2 and then to evacuate the exhaust gas out of the heat treatment apparatus 1.

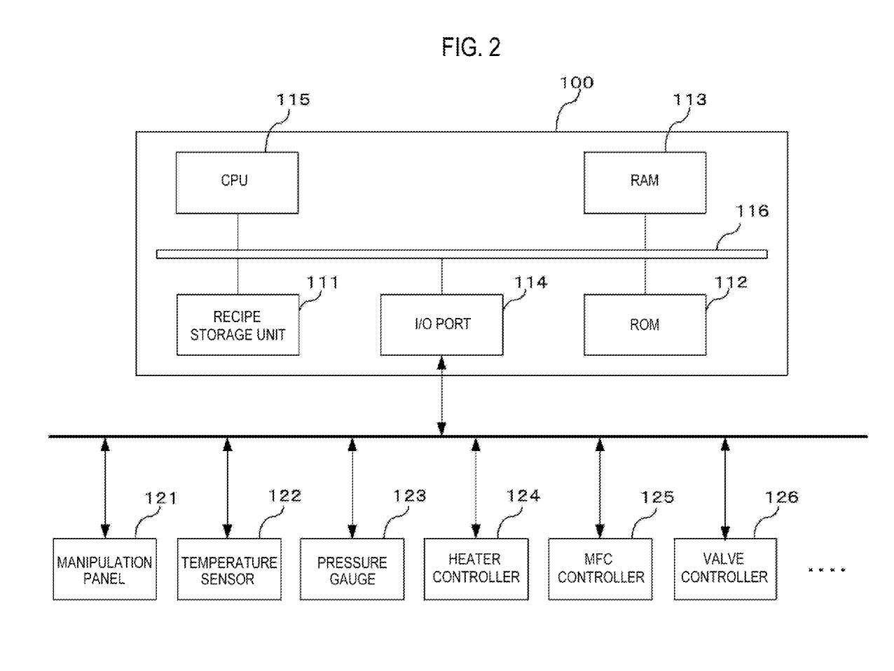

Further, the heat treatment apparatus 1 includes a control unit 100 for controlling each component of the heat treatment apparatus. FIG. 2 shows a configuration of the control unit 100. As shown in FIG. 2, a manipulation panel 121, a temperature sensor (temperature sensor group) 122, a pressure gauge (pressure gauge group) 123, a heater controller 124, a MFC controller 125 and a valve controller 126 are connected to the control unit 100.

The manipulation panel 121 has a display screen and manipulation buttons. The manipulation panel 121 transmits operator's manipulation instructions to the control unit 100. Further, the manipulation panel 121 displays various information from the control unit 100 on the display screen.

The temperature sensor (temperature sensor group) 122 measures the temperature in each component such as the reaction tube 2, the processing gas introduction pipes 13, or the exhaust pipe 16. The temperature sensor (temperature sensor group) 122 informs the control unit 100 of such measured values.

The pressure gauge (pressure gauge group) 123 measures the pressure in each component such as the reaction tube 2, the processing gas introduction pipes 13, or the exhaust pipe 16. The pressure gauge (pressure gauge group) 123 informs the control unit 100 of such measured values.

The heater controller 124 controls each of the temperature raising heaters 12. The heater controller 124 electrifies and heats the temperature raising heaters 12 in response to the instructions from the control unit 100. Further, the heater controller 124 measures the electric power consumption of the respective temperature raising heaters 12 and informs the control unit 100 of such measured values.

The MFC controller 125 controls the mass flow controllers (MFC) (not shown) provided in the processing gas introduction pipes 13 and the purge gas supply pipe 15. The MFC controller 125 sets the flow rates of the gases, which flow through the processing gas introduction pipes 13 and the purge gas supply pipe 15, to the flow rates instructed by the control unit 100. Further, the MFC controller 125 measures the flow rates of the gases flowing and informs the control unit 100 of such measured values.

The valve controller 126 controls the opening degree of the valve disposed in each pipe to the values instructed by the control unit 100.

The control unit 100 includes a recipe storage unit 111, a read only memory (ROM) 112, a random access memory (RAM) 113, an input/output (I/O) port 114, a central processing unit (CPU) 115 and a bus 116 interconnecting those components.

A setup recipe and a plurality of process recipes are stored in the recipe storage unit 111. When the heat treatment apparatus 1 is manufactured, only the setup recipe is stored in the recipe storage unit 111. The setup recipe is executed when creating a thermal model suitable for each heat treatment apparatus. The process recipe is prepared for every heat treatment (process) which the user really performs. For example, the process recipe prescribes the temperature change in each component, the pressure change in the reaction tube 2, the timing of beginning and stopping the supply of the processing gas, the supply amount of the processing gas, etc. from the time of loading the semiconductor wafers 10 into the reaction tube 2 until the time of unloading the processed semiconductor wafers 10.

The ROM 112 includes an electrically erasable programmable read only memory (EEPROM), a flash memory, a hard disc or the like. The ROM 112 is a recording medium which stores an operating program of the CPU 115.

The RAM 113 functions as a work area of the CPU 115.

The I/O port 114 is connected to the manipulation panel 121, the temperature sensor (temperature sensor group) 122, the pressure gauge (pressure gauge group) 123, the heater controller 124, the MFC controller 125 and the valve controller 126. The I/O port 114 controls the input and output of data or signals.

The CPU 115 constitutes the center of the control unit 100. The CPU 115 executes the operating program stored in the ROM 112 and controls the operation of the heat treatment apparatus 1 along the recipe (the process recipe) stored in the recipe storage unit 111 in accordance with the instructions from the manipulation panel 121. That is, the CPU 115 allows the temperature sensor (temperature sensor group) 122, the pressure gauge (pressure gauge group) 123 and the MFC controller 125 to measure the temperature, the pressure and the flow rate in each component such as the reaction tube 2, the processing gas introduction pipes 13 and the exhaust pipe 16. Based on those measured data, the CPU 115 outputs control signals to the heater controller 124, the MFC controller 125 and the valve controller 126 and controls the aforementioned components such that they comply with the process recipe.

The bus 116 transmits information from one component to another component.

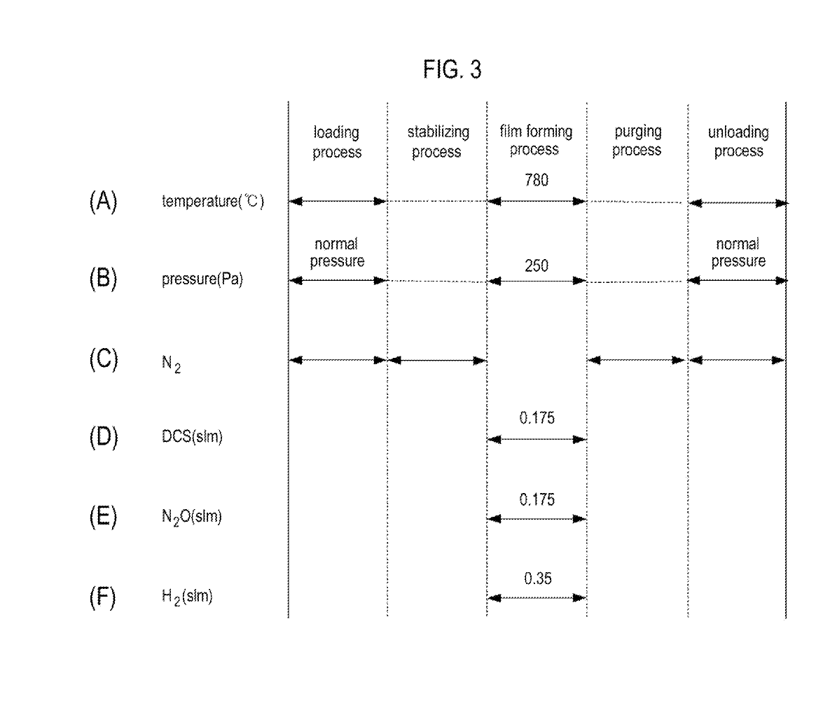

Next, descriptions will be made as to a silicon oxide film forming method, which uses the heat treatment apparatus 1 having the above-described configuration. In the following description, the control unit 100 (the CPU 115) controls the operation of each component constituting the heat treatment apparatus 1. Further, the temperature, the pressure, the gas flow rate, etc. in the reaction tube 2 in each process are set to the conditions complying with the recipe, for example, shown in FIG. 3, by controlling the heater controller 124 (the temperature raising heaters 12), the MFC controller 125, the valve controller 126, etc. through the control unit 100 (the CPU 115), as described above.

First, as shown by (A) of FIG. 3, the interior of the reaction tube 2 (the inner tube 3) is set to a predetermined temperature. Further, as shown by (C) of FIG. 3, a predetermined amount of nitrogen is supplied from the purge gas supply pipe 15 into the inner tube 3 (the reaction tube 2). Next, the wafer boat 9 which accommodates the semiconductor wafers 10 is placed on the lid 7. Then, the lid 7 is elevated by the boat elevator 8, thereby loading the semiconductor wafers 10 (the wafer boat 9) into the reaction tube 2 (loading process).

Subsequently, as shown by (C) of FIG. 3, a predetermined amount of nitrogen is supplied from the purge gas supply pipe 15 into the inner tube 3. Also, the interior of the reaction tube 2 is set to a predetermined temperature, for example, 780 degrees C., as shown by (A) of FIG. 3. Further, the gas in the reaction tube 2 is discharged and the reaction tube 2 is depressurized to a predetermined pressure, for example, 250 Pa (1.88 Torr) as shown by (B) of FIG. 3. Then, the interior of the reaction tube 2 is stabilized at the predetermined temperature and pressure (stabilizing process).

In a film forming process, the temperature in the reaction tube 2 may be preferably 600 to 1000 degrees C., more preferably 700 to 900 degrees C. Further, in the film forming process, the pressure in the reaction tube 2 may be preferably 1.33 to 1330 Pa (0.01 to 10 Torr), more preferably 13.3 to 665 Pa (0.1 to 5 Torr). When the temperature and pressure in the reaction tube 2 are set to the aforementioned ranges, the silicon oxide film can be more uniformly formed.

If the interior of the reaction tube 2 is stabilized at the predetermined temperature and pressure, the supply of nitrogen from the purge gas supply pipe 15 is stopped. Then, as shown by (D) of FIG. 3, a predetermined amount of the film forming gas, for example, DCS (the silicon source) is supplied from the processing gas introduction pipes 13 into the reaction tube 2 at a flow rate of 0.175 slm, and N₂O (the oxidizing agent) is supplied at a flow rate of 0.175 slm as shown by (E) of FIG. 3. Further, as shown by (F) of FIG. 3, hydrogen (H₂) gas is supplied at a flow rate of 0.35 slm (film forming process). By doing so, the silicon oxide film (HTO film) is formed on the surface of the semiconductor wafer 10.

In this embodiment, the hydrogen gas is supplied in the film forming process, thereby making the interior of the reaction tube 2 be under a hydrogen atmosphere (under a H₂ atmosphere). Thus, the silicon oxide film formed on the surface of the semiconductor wafer 10 is difficult to contain hydrogen atoms or chlorine atoms. Therefore, the etching resistance of the silicon oxide film is improved, and the device performance is not affected.

The supply amount of the hydrogen gas may be preferably 0.5 to 10 times, more preferably 0.8 to 5 times of the supply amount of DCS (silicon source). Because the formed silicon oxide film is difficult to contain the hydrogen atoms or the chlorine atoms, when the supply amount of the hydrogen gas is set to the aforementioned range, not only the etching resistance of the silicon oxide film is further improved but also the device performance is prevented from degradation. Most preferably, the supply amount of the hydrogen gas may be 1 to 2.5 times of the supply amount of DCS. While the larger supply amount of the hydrogen gas results in the less amount of chlorine atoms in the silicon oxide, the large supply amount of the hydrogen gas may deteriorate the film formation rate of the HTO film.

If a predetermined amount of the silicon oxide film is formed on the semiconductor wafer 10, the processing gas introduction pipes 13 cease the supply of the film forming gas and the hydrogen gas. Next, as shown by (C) of FIG. 3, a predetermined amount of nitrogen is supplied from the purge gas supply pipe 15 into the inner tube 3, and the interior of the reaction tube 2 is set to a predetermined temperature as shown by (A) of FIG. 3. Further, the gas in the reaction tube 2 is discharged, and the pressure in the reaction tube 2 is restored to a normal pressure (purging process). Further, to completely discharge the gas in the reaction tube 2, it is preferred that the discharge of the gas in the reaction tube 2 and the supply of the nitrogen gas are repeated several times. Then, the boat elevator 8 lowers the lid 7, thereby unloading the semiconductor wafers 10 (the wafer boat 9) out of the interior of the reaction tube 2 (unloading process). By doing so, the formation of the silicon oxide film is finished.

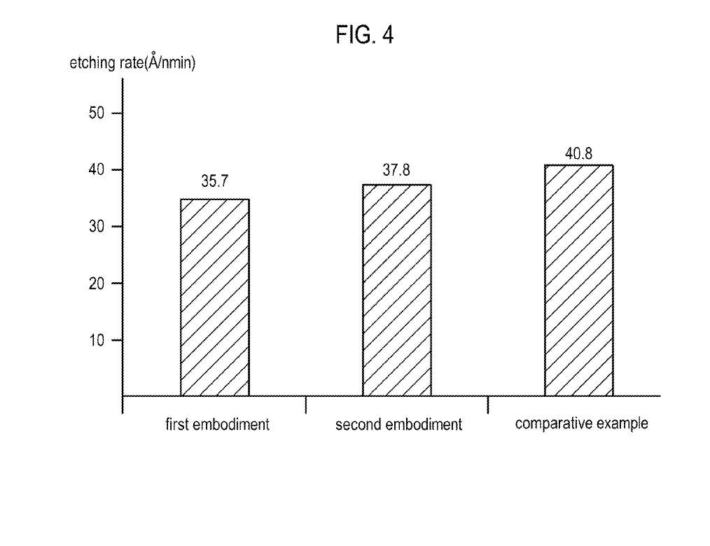

To confirm the effects of the silicon oxide film forming method according to the present disclosure, the silicon oxide film (HTO film) was formed on the semiconductor wafer 10 along the recipe shown in FIG. 3, and thereafter a wet etching rate of the HTO film was measured in DHF wherein DHF and deionized water (DIW) are mixed at a ratio of 50% DHF: DIW=1:200 (first embodiment). In addition, the wet etching rate of the HTO film in DHF was measured when the supply amount of the hydrogen (H₂) gas is set to the flow rate of 0.175 slm in the film forming process (second embodiment). Furthermore, the wet etching rate of the HTO film in DHF was measured for purposes of comparison when the hydrogen (H₂) gas is not supplied in the film forming process (comparative example). FIG. 4 shows the measured results.

As shown in FIG. 4, supplying the hydrogen gas in the film forming process may reduce the wet etching rate of the HTO film in DHF by 10% or more and thus improves the resistance against DHF.

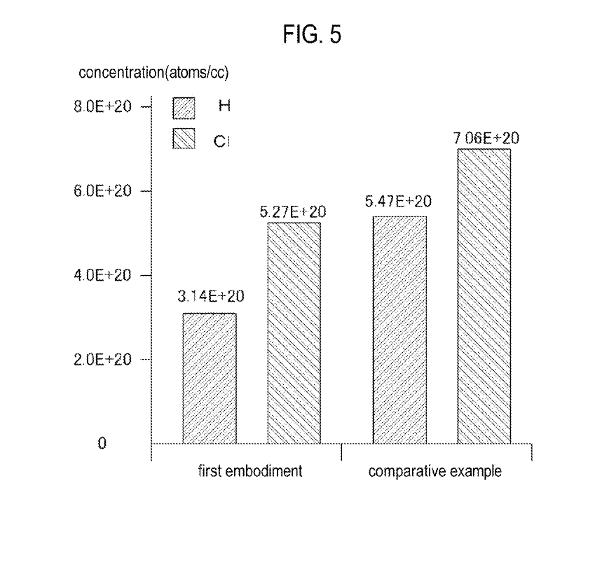

Further, the concentration of hydrogen (the number of hydrogen atoms) contained in the silicon oxide film and the concentration of chlorine (the number of chlorine atoms) contained in the silicon oxide film were measured with respect to the first embodiment and the comparative example. FIG. 5 shows the measured results. As shown in FIG. 5, the hydrogen concentration and the chlorine concentration are reduced in the first embodiment when compared with the comparative example. Supplying the hydrogen gas in the film forming process may reduce the hydrogen concentration and the chlorine concentration in the formed silicon oxide film.

Accordingly, supplying the hydrogen gas in the film forming process may improve the etching resistance and may prevent degradation of the device performance.

As described hereinbefore, according to the embodiments of the present disclosure, the hydrogen gas is supplied in the film forming process for forming the silicon oxide film, thus improving the etching resistance and not degrading the device performance.

Various other changes and application may be made from the hereinbefore-described embodiments. Other embodiments which may fall within the present disclosure will be described below.

The foregoing embodiments are described with an example where DCS is used as the film forming gas. However, the film forming gas may include a chlorine atom-containing silicon source such as tetrachlorosilane, trichlorosilane or hexachlorodisilane (HCD). Further, the oxidizing agent may include nitrogen monoxide (NO), nitrogen dioxide (NO₂) or ozone (O₃).

The foregoing embodiments are described with an example where the vertical batch-type heat treatment apparatus having a double tube structure is used as the heat treatment apparatus. However, a batch-type heat treatment apparatus having a single-tube structure may be used as the heat treatment apparatus.

The control unit 100 according to the embodiments may be realized using a normal computer system, regardless of a dedicated system. For example, the control unit 100, which executes the above-described processes, may be constructed by, for example, installing a program for executing the above-described processes in a general-purpose computer from a recording medium (a flexible disc, a CD-ROM, etc.) which stores said program.

Means for supplying such programs is arbitrary. The programs may be supplied through the aforementioned predetermined recording medium. Further, the programs may be supplied through, for example, a communication line, a communication network, a communication system or the like. In such a case, the programs may be posted on, for example, a bulletin board system (BBS) of a communication network and may be supplied through a network as superimposed on a carrier wave. The above-described processes may be performed by activating the program supplied in the aforementioned manner and executing it under the control of an operating system (OS) in the same manner as other application programs.

The present disclosure provides the embodiments of the silicon oxide film forming method and apparatus, which improve the etching resistance but do not degrade the device performance.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a silicone oxide film, comprising:
forming a silicon oxide film on a plurality of target objects by supplying a chlorine atom-containing silicon source into a reaction chamber accommodating the plurality of target objects,
wherein forming the silicon oxide film includes making an interior of the reaction chamber be under a hydrogen atmosphere by supplying a hydrogen gas into the reaction chamber.

2. The method of claim 1, wherein the chlorine atom-containing silicon source includes one of tetrachlorosilane, trichlorosilane, dichlorosilane, monochlorosilane and hexachlorodisilane.

3. The method of claim 1, wherein a temperature in the reaction chamber is maintained at 600 to 1000 degrees C. at forming the silicone oxide film.

4. The method of claim 1, wherein a supply amount of the hydrogen gas supplied into the reaction chamber is 0.5 to 5 times of a supply amount of the chlorine atom-containing silicon source.

5. A silicone oxide film forming apparatus, comprising:
a film forming gas supply unit configured to supply a film forming gas into a reaction chamber accommodating a plurality of target objects, the film forming gas having a chlorine atom-containing silicon source;
a hydrogen supply unit configured to supply a hydrogen gas into the reaction chamber; and
a control unit configured to control the film forming gas supply unit and the hydrogen supply unit,
wherein the control unit controls the hydrogen supply unit such that the hydrogen supply unit supplies the hydrogen gas into the reaction chamber, thus making an interior of the reaction chamber be under a hydrogen atmosphere, and
wherein the control unit controls the film forming gas supply unit such that the film forming gas supply unit supplies the film forming gas into the reaction chamber, thus forming a silicon oxide film on the plurality of target objects.

6. The apparatus of claim 5, wherein the chlorine atom-containing silicon source includes one of tetrachlorosilane, trichlorosilane, dichlorosilane, monochlorosilane and hexachlorodisilane.
